(19) United States
(12) Patent Application Publication
(10) Pub. No.: US 2022/0117118 A1
(43) Pub. Date: Apr. 14, 2022

(54) COOLING DEVICE

(71) Applicant: Nidec Chaun-Choung Technology Corporation, New Taipei City (TW)

(72) Inventors: Jason WANG, New Taipei City (TW); Vivian HSU, New Taipei City (TW); Lily WANG, New Taipei City (TW)

(21) Appl. No.: 17/499,378

(22) Filed: Oct. 12, 2021

(30) Foreign Application Priority Data
Oct. 12, 2020 (JP) 2020-172234

(51) Int. Cl. H05K 7/20; F28D 15/04; F28D 15/02

(52) U.S. Cl. CPC H05K 7/20336; F28D 15/0233; F28D 15/046

(57) ABSTRACT

A cooling device includes a thermal conductor and a cooler. The thermal conductor includes a working medium, a wick, and a metallic housing. The housing includes an internal space to accommodate the working medium and the wick. The cooler includes an internal flow path through which a fluid can flow, and is connected to an end portion of the thermal conductor.

### CROSS-REFERENCE TO RELATED APPLICATIONS

The present application claims priority under 35 U.S.C. § 119 to Japanese Patent Application No. 2020-172234, filed on Oct. 12, 2020, the entire contents of which are hereby incorporated herein by reference.

### 1. Field of the Invention

The present disclosure relates to a cooling device.

### 2. Background

Conventionally, a vapor chamber is known as a thermal conductor that dissipates heat generated by a heat generation source. The vapor chamber is often used for cooling a heat generating component such as a CPU in an electronic device such as a personal computer.

Meanwhile, with improvement in performance of information devices and an increase in speed of information processing, the amount of heat generation accompanying these also tends to increase in recent years. Therefore, there is a case where further improvement in cooling performance of the vapor chamber is desired.

### SUMMARY

An example embodiment of a cooling device of the present disclosure includes a thermal conductor and a cooler. The thermal conductor includes a working medium, a wick, and a metallic housing. The housing includes an internal space to accommodate the working medium and the wick. The cooler includes an internal flow path through which a fluid can flow, and is connected to an end portion of the thermal conductor.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view illustrating a configuration example of a cooling device according to an example embodiment of the present disclosure.

FIG. 2 is a cross-sectional view illustrating a configuration example of a thermal conductor according to an example embodiment of the present disclosure.

FIG. 3 is a cross-sectional view illustrating a first modification of a thermal conductor according to an example embodiment of the present disclosure.

FIG. 4 is a cross-sectional view illustrating a second modification of a thermal conductor according to an example embodiment of the present disclosure.

FIG. 5 is a perspective view illustrating another configuration example of a cooling device according to an example embodiment of the present disclosure.

### DETAILED DESCRIPTION

Hereinafter, example embodiments will be described with reference to the drawings.

In the present specification, a longitudinal direction of a plate-shaped thermal conductor 1, which will be described later, is referred to as a “first direction D1”. One side in the first direction D1 is referred to as “one side in the first direction D1a”, and the other side is referred to as “the other side in the first direction D1b”. In each component, an end portion on the one side in the first direction D1a is referred to as “one end portion in the first direction”, and an end portion on the other side in the first direction D1b is referred to as “the other end portion in the first direction”. Among surfaces of each component, a surface facing the one side in the first direction D1a is sometimes referred to as “one end surface in the first direction”, and a surface facing the other side in the first direction is sometimes referred to as “the other end surface in the first direction”.

In addition, a lateral direction of the plate-shaped thermal conductor 1 is referred to as a “second direction D2”. One side in the second direction D2 is referred to as “one side in the second direction D2a”, and the other side is referred to as “the other side in the second direction D2b”. In each component, an end portion on the one side in the second direction D2a is referred to as “one end portion in the second direction”, and an end portion on the other side in the second direction D2b is referred to as “the other end portion in the second direction”. Among surfaces of each component, a surface facing the one side in the second direction D2a is sometimes referred to as “one end surface in the second direction”, and a surface facing the other side in the second direction is sometimes referred to as “the other end surface in the second direction”.

In addition, a direction perpendicular to both the first direction D1 and the second direction D2 is referred to as a “third direction D3”. One side in the third direction D3 is referred to as “one side in the third direction D3a”, and the other side is referred to as “the other side in the third direction D3b”. In each component, an end portion on the one side in the third direction D3a is referred to as “one end portion in the third direction”, and an end portion on the other side in the third direction D3b is referred to as “the other end portion in the third direction”. Among surfaces of each component, a surface facing the one side in the third direction D3a is sometimes referred to as “one end surface in the third direction”, and a surface facing the other side in the third direction is sometimes referred to as “the other end surface in the third direction”.

In a positional relationship between any one element and another element of an orientation, a line, and a surface, the term “parallel” includes not only a state in which these elements endlessly extend without intersecting at all but also a state in which these elements are substantially parallel. The terms “perpendicular” and “orthogonal” each include not only a state in which the both intersect at 90 degrees with each other but also a state in which the both are substantially perpendicular and a state in which the both are substantially orthogonal. In other words, the terms “parallel”, “perpendicular”, and “orthogonal” each include a state in which the positional relationship therebetween permits an angular deviation to a degree not departing from the gist of the present disclosure.

The “plate shape” includes not only a shape that spreads completely flat without unevenness and bending in a direction perpendicular to a predetermined normal direction but also a shape that spreads substantially flat. That is, the “plate shape” includes a shape that spreads flat in the direction perpendicular to the predetermined normal direction with an uneven and bent portion to a degree not departing from the gist of the present disclosure.

Note that these are names used merely for description, and are not intended to limit actual positional relationships, directions, shapes, names, and the like.

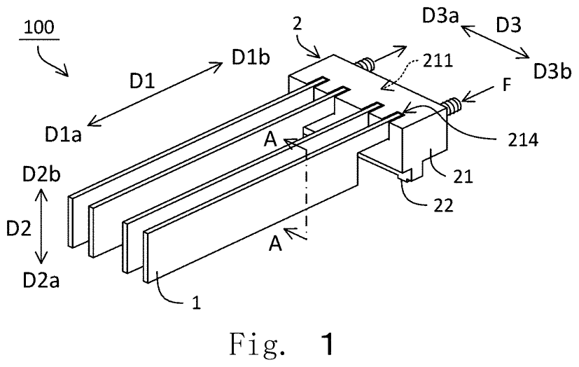

FIG. 1 is a perspective view illustrating a configuration example of a cooling device 100. As illustrated in FIG. 1, the cooling device 100 includes the thermal conductor 1 and a cooler 2.

The thermal conductor 1 is disposed near a heat source to cool the heat source. The heat source is an electronic component mounted on an electronic device, and is, for example, a CPU, a power device, a memory module, or the like. The thermal conductor 1 includes a metallic housing 11, a wick structure 12, and a working medium 13. In addition, the housing 11 has an internal space 113 for accommodating the wick structure 12 and the working medium 13 as will be described later. The thermal conductor 1 has a plate shape in the present example embodiment. The thermal conductor 1 extends from the cooler 2 in the one side in the first direction D1a and spreads in the second direction D2 perpendicular to the first direction D1.

As described above, the cooling device 100 includes the cooler 2. The cooler 2 has an internal flow path 211 through which a fluid F can flow as will be described later. The cooler 2 is connected to an end portion of the thermal conductor 1 so as to be capable of transferring heat. Specifically, the other end portion in the first direction of the thermal conductor 1 is connected to the cooler 2 so as to be capable of conducting heat. Note that the fluid F is a refrigerant. As the fluid F, for example, antifreeze, such as ethylene glycol and propylene glycol, or a liquid, such as pure water, can be employed.

In the internal space 113 of the thermal conductor 1, the working medium 13 is vaporized by the heat transferred from the heat source and moves toward the end portion of the thermal conductor 1 connected to the cooler 2. The heat transferred to the thermal conductor 1 is dissipated to the cooler 2 at the end portion of the thermal conductor 1. Since the fluid F flows through the internal flow path 211 of the cooler 2, the cooler 2 can efficiently release the heat transferred from the thermal conductor 1 to the fluid F. Therefore, the vaporized working medium 13 can efficiently dissipate the heat to the cooler 2 to be liquefied. The liquefied working medium 13 permeates the wick structure 12 and moves toward the heat source. In the cooling device 100, the above vaporization-liquefaction cycle of the working medium 13 can be efficiently implemented. Therefore, a heat transfer property of the thermal conductor 1 can be further improved, and thus, the cooling performance of the thermal conductor 1 can be further enhanced.

The plurality of the thermal conductors 1 are arranged in the third direction D3. This facilitates cooling of a plurality of heat sources arranged in the third direction D3. For example, the thermal conductors 1 can be disposed next to the heat sources, respectively, in the third direction D3 to cool the heat sources. Note that four thermal conductors 1 are disposed in the cooling device 100 in the present example embodiment. However, the present disclosure is not limited to this example, and the number of the thermal conductors 1 may be one, or two or more except for four.

The cooler 2 is a member configured to cool the thermal conductor 1. The cooler 2 includes a jacket portion 21 in which the internal flow path 211 is disposed. The jacket portion 21 includes the above-described internal flow path 211, an inlet 212, and an outlet 213. The internal flow path 211 is a flow path through which the fluid F flows, and is disposed inside the jacket portion 21. The internal flow path 211 is connected to the inlet 212 and the outlet 213. The inlet 212 and the outlet 213 are connected to a pump device (not illustrated) that circulates the fluid F, a radiator device (not illustrated) that cools the fluid F, and the like. As the pump device is driven, the fluid F circulates through the internal flow path 211, the radiator device, and the pump device.

The fluid F flows into the internal flow path 211 from the inlet 212. While the fluid F flows inside the internal flow path 211, heat transferred from the thermal conductor 1 to the jacket portion 21 is released to the fluid F. The fluid F to which the heat has been transferred flows out to the outside of the internal flow path 211 from the outlet 213 and is cooled by the radiator device. The cooled fluid F returns to the internal flow path 211 and flows again from the inlet 212. The cooler 2 can cool the thermal conductor 1 through the above heat transfer cycle.

The jacket portion 21 further includes a recess 214. That is, the cooler 2 has the recess 214. A part of the thermal conductor 1 is disposed in the recess 214. Specifically, the recess 214 is disposed at one end portion in the first direction of the jacket portion 21 and is recessed toward the other side in the first direction D1b. The recess 214 accommodates the other end portion in the first direction of the thermal conductor 1, so that the thermal conductor 1 is fixed and supported by the jacket portion 21. Note that the other end portion in the first direction of the thermal conductor 1 may be fixed by being press-fitted into the recess 214. Alternatively, the fixing may be performed by soldering using silver solder or the like, welding, and the like. Then, for example, a side surface of the end portion of the thermal conductor 1 is in contact with an inner side surface of the recess 214, so that a heat conduction area between the thermal conductor 1 and the cooler 2 can be further widened. Therefore, the cooling efficiency of the thermal conductor 1 by the cooler 2 can be enhanced.

A material of the jacket portion 21 is copper in the present example embodiment, but is not limited to this example. For example, any metal, such as copper, iron, aluminum, zinc, silver, gold, magnesium, manganese, and titanium, or an alloy (brass, stainless steel, duralumin, or the like) containing these metals can be used as the material of the jacket portion 21.

The cooler 2 further includes a leg portion 22. The leg portion 22 protrudes from one end portion in the second direction of the jacket portion to the one side in the second direction D2a. As the leg portion 22 is fixed to a predetermined member, the cooling device 100 can be fixed, and particularly, the thermal conductor 1 can be fixed via the cooler 2.

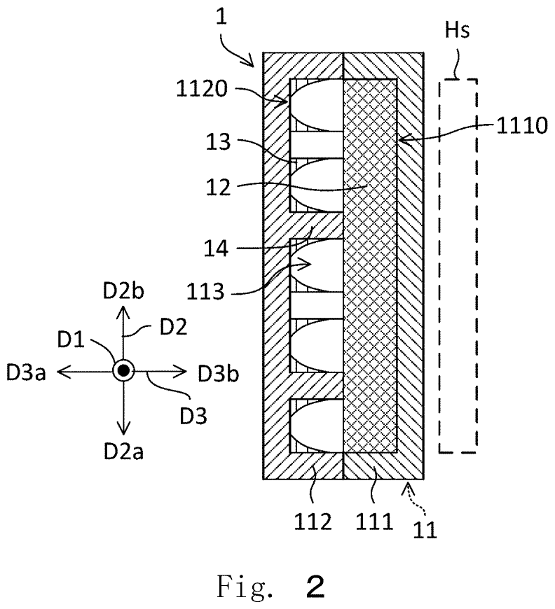

Next, a configuration of the thermal conductor 1 will be described with reference to FIGS. 1 and 2. FIG. 2 is a cross-sectional view illustrating a configuration example of the thermal conductor. Note that FIG. 2 illustrates a cross-sectional structure of the thermal conductor 1 taken along an alternate long and short dash line A-A in FIG. 1. In FIG. 2, a heat source Hs releasing heat to the thermal conductor 1 has a plate shape spreading in the first direction D1 and the second direction D2, and is disposed at a position opposite to the thermal conductor 1 in the third direction D3.

The thermal conductor 1 is a so-called vapor chamber, and cools the heat source disposed in the vicinity in the present example embodiment. The thermal conductor 1 includes the metallic housing 11, the wick structure 12, the working medium 13, and a column portion 14.

The other end portion in the first direction of the housing 11 is connected to the cooler 2 so as to be thermally conductive (see FIG. 1). In addition, one end portion in the second direction of the other end portion in the first direction of the housing 11 is disposed on the other side in the second direction with respect to one end portion in the second direction of a portion on the one side in the first direction of the housing 11. Then, when the thermal conductor 1 is disposed such that the one side in the second direction D2a is directed vertically downward, the working medium 13 liquefied at the other end portion in the first direction of the internal space 113 of the housing 11 easily flows into a portion on the one side in the first direction of the internal space 113 due to a height difference in the vertical direction. Therefore, the heat transfer efficiency of the thermal conductor 1 can be further improved.

The housing 11 includes a first metal plate 111 and a second metal plate 112. In the third direction D3, the first metal plate 111 is disposed opposite to the second metal plate 112. The first metal plate 111 has a recess 1110. The recess 1110 is disposed at one end portion in the third direction of the first metal plate 111 and is recessed to the other side in the third direction D3b. The second metal plate 112 has a recess 1120 overlapping with the recess 1110 when viewed from the third direction D3. The recess 1120 is disposed at the other end portion in the third direction of the second metal plate 112 and is recessed to the one side in the third direction D3a.

Further, the housing 11 has the internal space 113 for accommodating the wick structure 12 and the working medium 13. The internal space 113 is disposed between the first metal plate 111 and the second metal plate 112. Specifically, outer peripheral edges of the first metal plate 111 and the second metal plate 112 are joined to each other, whereby the sealed internal space 113 is formed inside the housing 11. The recess 1110 and the recess 1120 form the internal space 113 in the present example embodiment. Note that the present disclosure is not limited to this example, and either the recess 1110 or the recess 1120 may be omitted. That is, the internal space 113 is formed of at least one of the recess 1110 of the first metal plate 111 and the recess 1120 of the second metal plate 112.

In the present example embodiment, the first metal plate 111 and the second metal plate 112 are joined by hot pressing. However, the present disclosure is not limited to this example, and the both may be joined by soldering or welding using, for example, silver solder or the like. Further, the both may be directly joined, or may be joined via a metal plating layer such as copper.

A material of the first metal plate 111 and the second metal plate 112 is copper in the present example embodiment. However, materials of the first metal plate 111 and the second metal plate 112 are not limited to the above example. For example, any metal, such as copper, iron, aluminum, zinc, silver, gold, magnesium, manganese, and titanium, or an alloy (brass, stainless steel, duralumin, or the like) containing these metals can be used as the materials of the first metal plate 111 and the second metal plate 112.

Next, the wick structure 12 has a capillary structure. The liquefied working medium 13 can permeate the wick structure 12. In the present example embodiment, the wick structure 12 is a porous metallic sintered body such as a sintered body of metal powder such as copper. However, the wick structure 12 is not limited to this example. The wick structure 12 may have a mesh shape. Alternatively, at least a part of the wick structure 12 may be a part of the housing 11, and may include, for example, a plurality of grooves disposed on a surface of the first metal plate 111 facing the second metal plate 112. A material of the wick structure 12 is copper in the present example embodiment. However, the present disclosure is not limited to this example, and another metal or alloys, carbon fibers, and ceramics may be adopted.

The wick structure 12 is disposed on an inner surface of the internal space 113 facing the third direction D3 perpendicular to the first direction D1 and the second direction D2. Then, the heat from the heat source Hs can be transferred to an outer side surface of the thermal conductor 1 spreading in the first direction D1 and the second direction D2. That is, an area in which heat can be transferred from the heat source Hs to the thermal conductor 1 can be further widened.

Specifically, the wick structure 12 is disposed on the inner surface on the first metal plate 111 side in the internal space 113, and is disposed on a bottom surface of the recess 1110 of the first metal plate 111 in the present example embodiment. In other words, the wick structure 12 is disposed on the inner surface of the internal space 113 on the heat source Hs side. That is, the wick structure 12 is disposed on the side to which heat is transferred from the heat source Hs in the internal space 113. Then, the heat can be efficiently transferred from the heat source Hs to the wick structure 12 into which the liquid working medium 13 penetrates, and thus, the cooling efficiency of the heat source Hs can be improved.

Next, the working medium 13 is vaporized by the heat transferred from the heat source Hs and evaporates in the internal space 113. Here, preferably, the sealed internal space 113 is depressurized and its internal pressure is lower than atmospheric pressure. Then, the working medium 13 is more easily vaporized.

The working medium 13 is cooled and liquefied at a portion of the housing 11 away from the heat source Hs. The liquefied working medium 13 penetrates into the wick structure 12 and is refluxed to the vicinity of a portion with which the heat source Hs is in contact. Through the above cycle in which the working medium 13 is vaporized and liquefied, the thermal conductor 1 can transfer the heat, which has been transferred from the heat source Hs, to the portion of the housing 11 away from the heat source Hs and dissipate the heat.

The working medium 13 is pure water in the present example embodiment, but may be a medium other than water. For example, the working medium 13 may be any of alcohol compounds such as methanol and ethanol, alternatives for chlorofluorocarbons such as hydrofluorocarbon, hydrocarbon compounds such as propane and isobutane, fluorinated hydrocarbon compounds such as difluoromethane, ethylene glycol, and the like. The working medium 13 can be employed according to a use environment of the thermal conductor 1.

Next, the column portion 14 protrudes from the second metal plate 112 toward the first metal plate 111 and is disposed inside the internal space 113 in the present example embodiment. More specifically, the column portion 14 protrudes from a bottom surface of the recess 1120 toward the first metal plate 111. In the present example embodiment, a plurality of the column portions 14 are disposed integrally with the second metal plate 112. That is, the column portion 14 and the second metal plate 112 are respectively different parts of the single member. However, the present disclosure is not limited to this example, and the column portion 14 may be a single member or a member different from the second metal plate 112.

A distal end of the column portion 14 is in contact with the wick structure 12 in the present example embodiment. Alternatively, the distal end may be in contact with the first metal plate 111 through a through-hole provided in the wick structure 12. As a result, the column portion 14 supports the first metal plate 111 and the second metal plate 112 between the both. Therefore, even when a force acts on an outer side surface of the first metal plate 111 and/or the second metal plate 112, the housing 11 is less likely to be deformed, and it is possible to suppress narrowing of the internal space 113 due to the deformation of the housing 11. Note that the present disclosure is not limited to the example of the present example embodiment, and at least a part of the column portion 14 may protrude from the first metal plate 111.

Next, modifications of the thermal conductor 1 will be described. In each modification, a configuration different from that of the above example embodiment and other modifications will be described. Moreover, configurations similar to those in the above example embodiments and other modifications will be denoted by the same reference signs, and detailed descriptions thereof will be omitted.

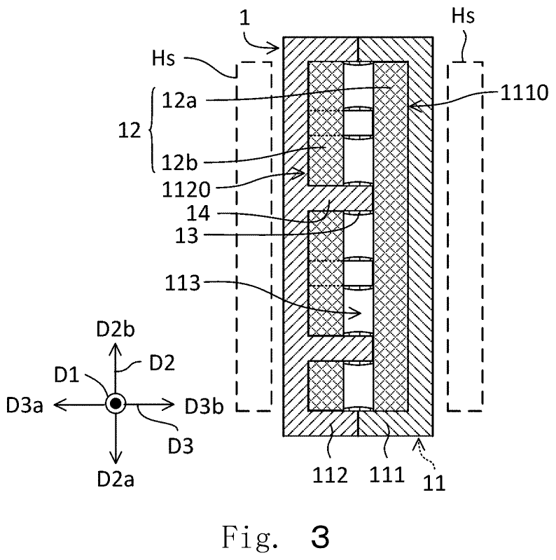

First, a first modification of the thermal conductor 1 will be described with reference to FIG. 3. FIG. 3 is a cross-sectional view illustrating the first modification of the thermal conductor 1. Note that FIG. 3 corresponds to the cross-sectional structure of the thermal conductor 1 taken along the alternate long and short dash line A-A in FIG. 1.

In the first modification, the wick structures 12 are disposed on inner surfaces of the internal space 113 on both sides in the third direction D3. For example, as illustrated in FIG. 3, the wick structures 12 include a first wick structure 12a and a second wick structure 12b. The first wick structure 12a is disposed on the inner surface of the internal space 113 facing the one side in the third direction D3a. The second wick structure 12b is disposed on the inner surface of the internal space 113 facing the other side in the third direction D3b. Note that a space for allowing the vaporized working medium 13 to move is disposed between the first wick structure 12a and the second wick structure 12b in the third direction D3. Then, the working medium 13 which is the liquid can be vaporized on both the sides in the third direction D3 in the internal space 113 of the thermal conductor 1. Therefore, the thermal conductor 1 can efficiently dissipate the heat, which has been transferred to both side surfaces of the housing 11 in the third direction D3, to the cooler 2. Thus, the thermal conductor 1 can cool, for example, the heat sources Hs disposed on both the sides in the third direction D3.

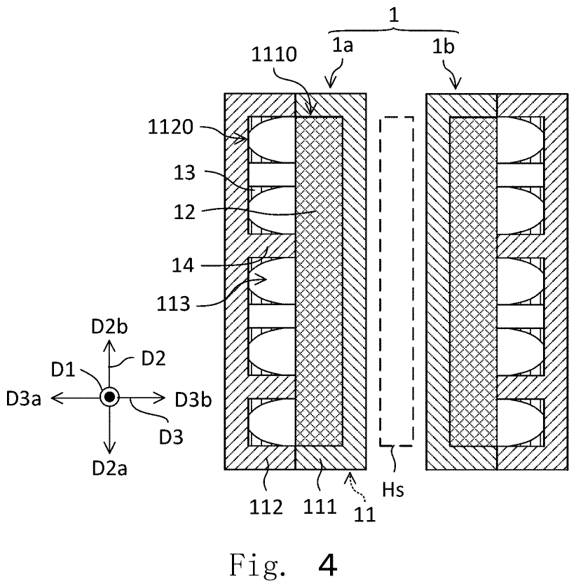

Next, a second modification of the thermal conductor 1 will be described with reference to FIG. 4. FIG. 4 is a cross-sectional view illustrating the second modification of the thermal conductor 1. Note that FIG. 4 corresponds to the cross-sectional structure of the thermal conductor 1 taken along the alternate long and short dash line A-A in FIG. 1.

In the second modification, the plurality of thermal conductors 1 include a first thermal conductor 1a and a second thermal conductor 1b. The first thermal conductor 1a is adjacent to the second thermal conductor 1b in the third direction D3, and is disposed on the one side in the third direction D3a with respect to the second thermal conductor 1b. Specifically, the first thermal conductor 1a and the second thermal conductor 1b are adjacent to each other with the heat source Hs interposed therebetween in the third direction D3. The first thermal conductor 1a is disposed on the one side in the third direction D3a with respect to the heat source Hs. The wick structure 12 of the first thermal conductor 1a is disposed on the inner surface of the internal space 113 facing the one side in the third direction D3a. The second thermal conductor 1b is disposed on the other side in the third direction D3b with respect to the heat source Hs. The wick structure 12 of the second thermal conductor 1b is disposed on the inner surface of the internal space 113 facing the other side in the third direction D3b. Thus, the heat source Hs disposed between the first thermal conductor 1a and the second thermal conductor 1b can be cooled from both the sides in the third direction D3. Therefore, a cooling effect of the heat source Hs can be improved. This effect is particularly advantageous in a case where heat is easily generated on both sides in the third direction of the heat source Hs.

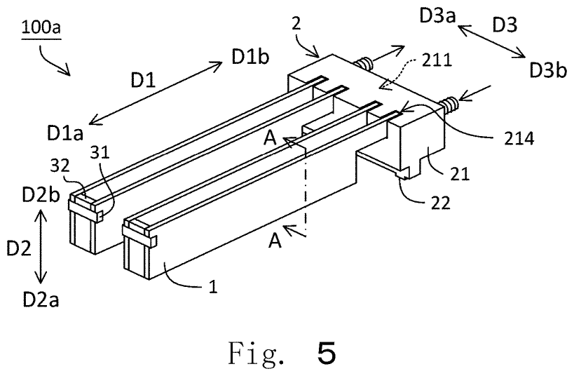

In the cooling device 100 described above, the one end portion in the first direction of each of the thermal conductors 1 is not supported and is a free end. Therefore, for example, when a force is applied from the outside, there is a possibility that an interval between the one end portions in the first direction of the respective thermal conductors 1 in the third direction D3 changes. Therefore, the cooling device 100 may include a member that suppresses movement of the one end portion in the first direction of the thermal conductor 1. FIG. 5 is a perspective view illustrating another configuration example of the cooling device 100.

A cooling device 100a illustrated in FIG. 5 further includes a coupler 31. The coupler 31 connects one end portions in the first direction of at least two thermal conductors 1. For example, in FIG. 5, the one end portions in the first direction of the thermal conductors adjacent to each other in the third direction D3 are connected to each other. Then, the one end portions in the first direction of the at least two thermal conductors 1 can be suppressed from moving in the third direction D3. For example, in FIG. 5, it is possible to suppress widening of an interval between the one end portions in the first direction of the thermal conductors adjacent to each other in the third direction D3.

The cooling device 100a illustrated in FIG. 5 further includes a spacer 32. The spacer 32 is interposed between the thermal conductors 1 adjacent to each other in the third direction D3. Preferably, the spacer 32 is disposed between the one end portions in the first direction of the thermal conductors 1 adjacent to each other in the third direction D3 as illustrated in FIG. 5. Then, the thermal conductors 1 adjacent to each other in the third direction D3 can be coupled with the spacer 32 interposed therebetween. Therefore, it is possible to suppress narrowing of the interval between the both in the third direction D3.

The present disclosure is advantageous for a device that performs cooling using a thermal conductor such as a vapor chamber.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a thermal conductor; and
a cooler; wherein
the thermal conductor includes a working medium, a wick, and a metallic housing;
the housing includes an internal space to accommodate the working medium and the wick; and
the cooler includes an internal flow path which allows flow of a fluid, and is connected to an end portion of the thermal conductor.

2. The cooling device according to claim 1, wherein
the cooler includes a recess; and
a portion of the thermal conductor is in the recess.

3. The cooling device according to claim 2, wherein
the thermal conductor extends from the cooler to one side in a first direction and spreads in a second direction perpendicular to the first direction; and
the wick is on an inner surface of the internal space opposing a third direction perpendicular to the first direction and the second direction.

4. The cooling device according to claim 3, wherein
another end portion in the first direction of the housing is connected to the cooler to be thermally conductive; and
one end portion in the second direction of the another end portion in the first direction of the housing is on another side in the second direction with respect to one end portion in the second direction of a portion of the housing on the one side in the first direction.

5. The cooling device according to claim 4, wherein
a plurality of the thermal conductors are arranged in the third direction.

6. The cooling device according to claim 3, wherein
the plurality of thermal conductors include a first thermal conductor and a second thermal conductor;
the first thermal conductor is adjacent to the second thermal conductor in the third direction and is on one side in the third direction with respect to the second thermal conductor;
the wick of the first thermal conductor is on an inner surface of the internal space opposing the one side in the third direction; and
the wick of the second thermal conductor is on an inner surface of the internal space opposing another side in the third direction.

7. The cooling device according to claim 3, wherein
the cooler includes:
a jacket portion in which the internal flow path is located; and
a leg portion protruding from one end portion in the second direction of the jacket portion to one side in the second direction.

8. The cooling device according to claim 5, further comprising
a coupler that connects first end portions of at least two thermal conductors among the thermal conductor in the first direction.

9. The cooling device according to claim 5, further comprising
a spacer interposed between a pair of the thermal conductors adjacent to each other in the third direction.

10. The cooling device according to claim 1, wherein
the housing includes a first metal plate and a second metal plate opposite to the first metal plate, and the internal space is between the first metal plate and the second metal plate; and
the wick includes:
a first wick on a surface of the first metal plate opposing the second metal plate; and
a second wick on a surface of the second metal plate opposing the first metal plate.
